(19) United States
(12) Patent Application Publication
(10) Pub. No.: US 2025/0357219 A1
(43) Pub. Date: Nov. 20, 2025

(54) GAS CONTROL IN SEMICONDUCTOR PROCESSING

(71) Applicant: Taiwan Semiconductor Manufacturing Company, Ltd., Hsinchu (TW)

(72) Inventors: Yen-Lin CHANG, Hsinchu City (TW); Pu-Kuan FANG, Hsinchu City (TW); Yung-Ta YEN, Hsinchu City (TW); Mu-Tsang LIN, Hsinchu City (TW)

(73) Assignee: Taiwan Semiconductor Manufacturing Company, Ltd., Hsinchu (TW)

(21) Appl. No.: 19/290,803

(22) Filed: Aug. 5, 2025

Related U.S. Application Data
(62) Division of application No. 17/453,105, filed on Nov. 1, 2021.
(60) Provisional application No. 63/188,577, filed on May 14, 2021.

(51) Int. Cl. H01L 21/66; H01L 21/67

(52) U.S. Cl. CPC H01L 22/12; H01L 21/67253

(57) ABSTRACT

The present disclosure describes a method for controlling gas supplies and an example system for performing the method. The method includes providing a first setting to configure a gas supply device to supply a first gas mixture to a substrate carrier holding a first substrate. The method further includes receiving critical dimension (CD) data measured on the first substrate after the first substrate completes a process operation. The method further includes, in response to the CD data being outside a predetermined range, providing a second setting to configure the gas supply device to supply a second gas mixture to the substrate carrier holding a second substrate that has yet to undergo the process operation.

### CROSS-REFERENCE TO RELATED APPLICATION

This application is a divisional of U.S. patent application Ser. No. 17/453,105, filed on Nov. 1, 2021 and titled “Gas Control in Semiconductor Processing,” which claims the benefit of U.S. Provisional Patent Application No. 63/188,577, filed on May 14, 2021 and titled “Environment Control Methodology in Semiconductor Process (AI Multi-Gas Programmable Control),” both of which are incorporated herein by reference in their entireties.

### BACKGROUND

Environment control can be required for semiconductor processing both in a cleanroom and on a process station. After certain operations, substrates, such as wafers, can be placed in environmentally-controlled waiting stations. Environment control can include control of temperature, relative humidity (RH), and inert and process gases. Challenges exist for environment control when the substrates are in substrate carriers, such as front opening unified/universal pods (FOUPs), whether the substrates are being transferred between process stations or waiting to be processed.

### BRIEF DESCRIPTION OF THE DRAWINGS

Aspects of the present disclosure are best understood from the following detailed description when read with the accompanying figures.

FIG. 1 illustrates a diagram of a gas control system, in accordance with some embodiments.

FIG. 2 illustrates a diagram of a gas control device, in accordance with some embodiments.

FIG. 3 is a flow diagram of a method for controlling gas supplies, in accordance with some embodiments.

FIGS. 4A-9C illustrate various applications of a gas control method, in accordance with some embodiments.

FIG. 10 illustrates a diagram of a computing device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the embodiments and/or configurations discussed herein.

Spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. The terms “about” and “substantially” can refer to a percentage of the values as interpreted by those skilled in relevant art(s) in light of the teachings herein.

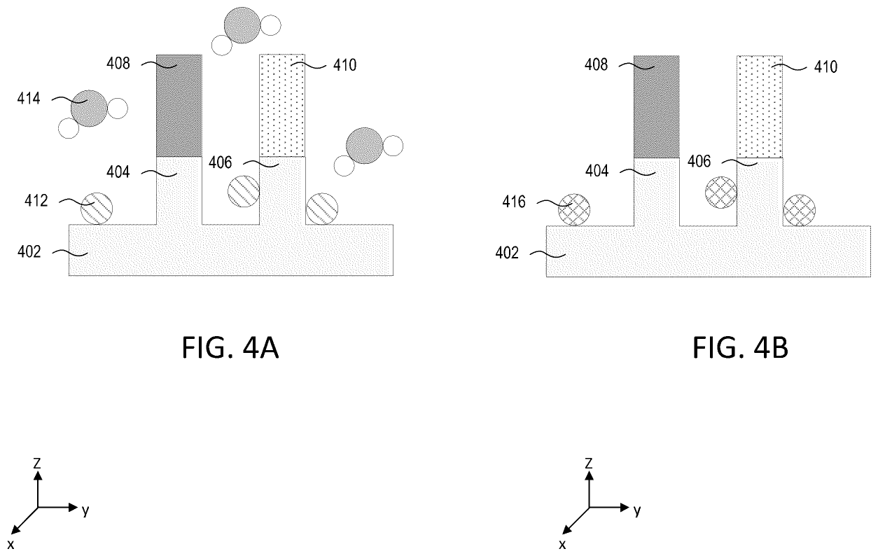

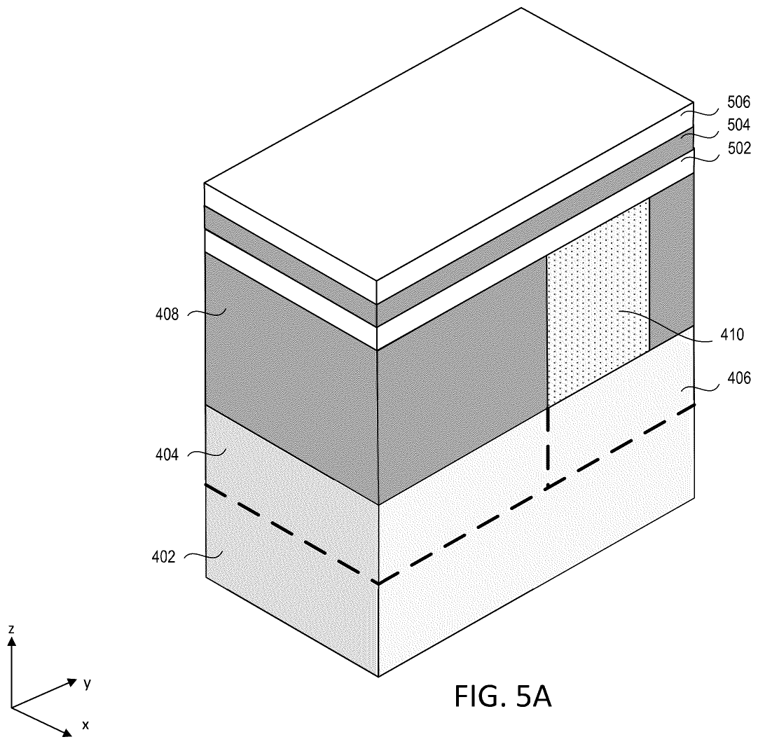

The discussion of elements in FIGS. 4A-6C and 7A-9C with the same annotations applies to each other, unless mentioned otherwise.

Environment control can be required for semiconductor processing both in a cleanroom and on a process station. After certain operations, substrates, such as wafers, can be placed in environmentally-controlled waiting stations. Environment control can include control of temperature, relative humidity (RH), and inert and process gases. Challenges exist for environment control when the substrates are in substrate carriers, such as front opening unified/universal pods (FOUPs), whether the substrates are being transferred between the process stations or waiting to be processed. For example, after certain etching processes using etchants containing chlorine (Cl) or fluorine (F), certain byproducts can react with water (H₂O) vapor and form contaminants on the surfaces of the substrates. Gas control can reduce the RH in the substrate carriers. In another example, certain structures on the substrates can suffer losses due to oxidation. Gas control can inject an inert gas, such as nitrogen (N₂) and Argon (Ar), in the substrate carriers to prevent oxidation on the structures. In some embodiments, oxidation can be a process operation to form an oxide layer. In some embodiments, oxidation can be used to tune surface roughness or trim critical dimensions (CDs). Gas control can inject a predetermined amount of oxygen (O₂) in the substrate carriers to generate a uniform oxide layer with a desired thickness. Challenges can exist for gas control in the substrate carriers.

The present disclosure is directed to a method for providing gas control to substrate carriers based on CD data feedback and an example system for performing the method. In some embodiments, a computing device can provide a gas supply setting to configure a gas supply device to supply a gas mixture to a substrate carrier holding a first substrate. After the first substrate completes a process operation, CD data can be measured on the first substrate. The computing device can receive and analyze the CD data measured on the first substrate. The CD data can depend on the different process operations and can include optical metrology data, optical inspection data, profilometer data, scanning electron microscopy (SEM) data, transmission electron microscopy (TEM) data, or a combination thereof. In response to the CD data being outside a predetermined range, the computing device can provide an adjusted gas supply setting to configure the gas supply device to supply an adjusted gas mixture to the substrate carrier holding a second substrate that has yet to undergo the process operation.

Based on the CD data, the computing device can adjust the types of the one or more gases, the amount of each of the one or more gases, the flow rate of each of the one or more gases, the supply duration of each of the one or more gases, and the ratios of the one or more gases. The adjusted gas supply setting can assist the second substrate in achieving CD data within the predetermined range. If the CD data measured on the second substrate remains outside the predetermined range, further adjustments can be made to the gas supply settings. Because the CD data can be monitored and fed into the gas supply settings constantly or periodically, gas supplies to the substrate carriers can be controlled to yield the CD data within the predetermined range. The gas control method and system can improve yield and quality. For example, the gas control method and system can reduce surface contaminants and oxidation loss. In some embodiments, the gas control method and system can facilitate oxidation while the substrates are waiting in the substrate carriers. The gas control method and system can also reduce oxidation time for the substrates during an oxidation process operation and can therefore reduce process cycle time and improve production efficiency. Because the gases in the substrate carriers can be controlled, and the substrate carriers can be airtight, the substrate carriers can function as environmentally-controlled waiting stations. Further, a number of gas-filled waiting stations can be reduced, which can save cleanroom floor space and reduce the operation costs.

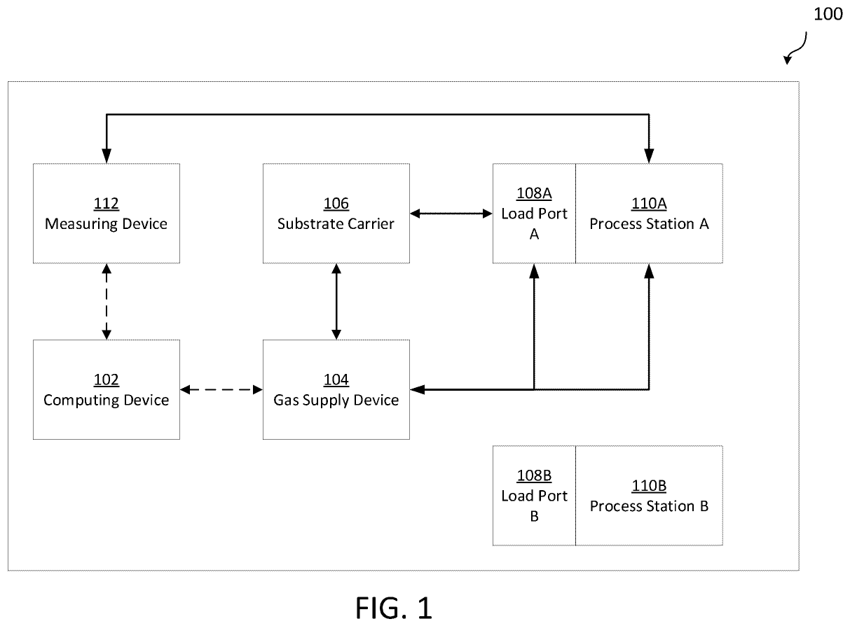

According to some embodiments, FIG. 1 illustrates a diagram of a gas control system 100. Gas control system 100 can include a computing device 102, a gas supply device 104, a substrate carrier 106, a number of process stations with load ports, such as process station A 110A with load port A 108A and process station B 110B with load port B 108B, and a measuring device 112. Gas control system 100 can be used to perform gas control method 300, which is described below.

Computing device 102 can provide gas supply settings to configure gas supply device 104 to supply gases to substrate carrier 106, load port A 108A, and process station A 110A. The gas supply settings can be provided to gas supply device 104 by wired and/or wireless means, which can include LANs, WANs, the Internet, Wi-Fi, Bluetooth, cable, light fiber, and any combination thereof. Computing device 102 can receive the CD data measured by measuring device 112 on the substrates. The CD data can be provided to computing device 102 by wired and/or wireless means. Computing device 102 can analyze the CD data and adjust the gas supply settings. In some embodiments, computing device 102 can feed the CD data into a mathematical model, and the mathematical model can adjust the gas supply settings based on predetermined criteria. In some embodiments, the mathematical model can be a multiple regression analysis model.

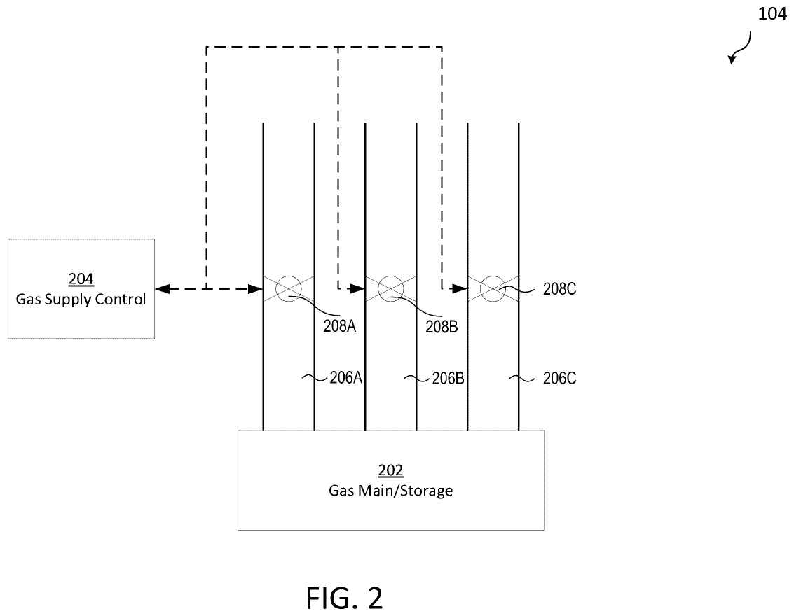

Gas supply device 104 can receive gas supply settings from computing device 102 and be configured to supply gases to substrate carrier 106, load port A 108A, and process station A 110A based on the gas supply settings. Gases supplied to substrate carrier 106, load port A 108A, and process station A 110A can be the same or different. The gas supply settings can include types of one or more gases, amount of each of the one or more gases, flow rate of each of the one or more gases, supply duration of each of the one or more gases, and ratios of the one or more gases. Referring to FIG. 2, in some embodiments, gas supply device 104 can include gas main and/or storage 202, gas supply control 204, conduits and/or pipes 206A-206C, and valves 208A-208C. Gas supply device 104 can also include pumps (not shown in FIG. 2).

Gas main and/or storage 202 can include main gas lines, pipes, and/or storage tanks that supply different gases. Gas main and/or storage 202 can also include multiple main gas lines, pipes, and/or storage tanks and each can supply one type of gas. Example gas types include extreme clean dry air (XCDA), O₂, N₂, Ar, hydrogen (H₂), and ammonia (NH₃). The same or different gases can be supplied to substrate carrier 106, load port A 108A, and process station A 110A via conduits and/or pipes 206A-206C. Each conduit and/or pipe 206A-206C can supply one type of gas. Conduits and/or pipes 206A-206C can be made of a suitable material, such as steel and plastic.

Gas supply control 204 can be an electronic component that can receive the gas supply settings and be configured to control valves 208A-208C. Valves 208A-208C can include actuated valves, automatic valves, and any combination thereof. Valves 208A-208C can include ball valves, butterfly valves, check valves, gate valves, knife gate valves, globe valves, needle valves, pinch valves, plug valves, pressure relief valves, and any combination thereof. Valves 208A-208C can be controlled to be fully or partially open and closed. By controlling valves 208A-208C to be fully open and closed, types of the one or more gases supplied and duration of each of the one or more gases can be controlled. By controlling valves 208A-208C to be fully or partially open and closed, amount of each of the one or more gases and flow rate of each of the one or more gases can be controlled. By controlling types, durations, amounts, and flow rates of the one or more gases, ratios of the one or more gases can be controlled.

In some embodiments, gas supply control 204 can assume the function of computing device 102. Gas supply control 204 can receive and analyze CD data and adjust the gas supply settings. Gas supply control 204 can control valves 208A-208C based on the gas supply settings by wired and/or wireless means. In some embodiments, gas supply device 104 can receive gases from substrate carrier 106, load port A 108A, and process station A 110A. For example, gas supply device 104 can extract exhaust gases from substrate carrier 106, load port A 108A, and process station A 110A using pumps (not shown in FIG. 2).

Referring to FIG. 1, substrate carrier 106 can carry and hold one or more substrates, such as wafers. The substrates can be a semiconductor material, such as silicon (Si), germanium (Ge), silicon germanium (SiGe), gallium arsenide (GaAs), gallium nitride (GaN), a silicon-on-insulator (SOI) structure, and any combination thereof. Substrate carrier 106 can be a FOUP. Substrate carrier 106 can have gas inlets and/or outlets such that substrate carrier 106 can exchange gases with gas supply device 104 and load port A 108A. Substrate carrier 106 can have openings such that substrate carrier 106 can exchange substrates with load port A 108A. In some embodiments, while some substrates are being processed on process station A 110A, it is crucial to supply certain gases to substrate carrier 106 such that the substrates waiting in substrate carrier 106 are protected from oxidation or H₂O vapor. In some embodiments, while some substrates are being processed on process station A 110A, certain gases can be supplied to substrate carrier 106 to react with the substrates in a similar manner as a next process operation such that cycle time can be saved on the next process operation. In some embodiments, the next process operation can be replaced completely by the reaction in substrate carrier 106. For example, a next process operation can be to grow an oxide layer of a predetermined thickness on a substrate. The time when the substrate waits for other substrates to finish processing on process station A 110A can be considered idle time. During the idle time, if a predetermined amount of O₂ can be injected into substrate carrier 106 to react with the substrate to grow the oxide layer of the predetermined thickness, the next process operation can be skipped. Production cycle time can be saved by performing the oxidation during the idle time.

When all the inlets, outlets, and openings are closed, substrate carrier 106 can be airtight. For example, in some embodiments, gases can stay in substrate carrier 106 for at least 12 hours. When substrate carrier 106 is transferred between process stations, such as process station A 110A and process station B 110B, or on stand-by, gases trapped in substrate carrier 106 can protect the substrates from oxidation or H₂O vapor or react with the substrates in a similar manner as a next process operation. For example, a next process operation can be to grow an oxide layer of a predetermined thickness on a substrate. The time when substrate carrier 106 transfers the substrate between process stations or when substrate carrier 106 holding the substrate is on stand-by can be considered idle time. During the idle time, if a predetermined amount of O₂ can be injected into substrate carrier 106 to react with the substrate to grow the oxide layer of the predetermined thickness, the next process operation can be skipped. Production cycle time can be saved by performing the oxidation during the idle time. Because the gases in substrate carrier 106 can be controlled, and substrate carrier 106 can be airtight, substrate carrier 106 can function as an environmentally-controlled waiting station. A number of gas-filled waiting stations can be reduced, which can save cleanroom floor space and reduce the operation costs.

Process station A 110A can process the substrates for one or more process operations. For example, process operations can include photolithography, etching, deposition, wet chemistry, cleaning, and anneal. The substrates can undergo one or more process operations on process station A 110A. Each process operation can require one gas mixture to be provided to process station A 110A by gas supply device 104. Process station A 110A can be equipped with load port A 108A. Load port A 108A can include a robotic arm. The robotic arm can move the substrates between substrate carrier 106 and load port A 108A. The robotic arm can have multiple degrees of freedom. The robotic arm can include a vacuum suction mechanism such that the substrates can be secured on the robotic arm during transfers between substrate carrier 106 and load port A 108A. Load port A 108A can require a gas mixture supplied by gas supply device 104. The gas mixture can be similar to or different from that supplied to substrate carrier 106 or process station A 110A.

Process station B 110B can process the substrates for one or more process operations that are the same as or different from the process operations performed by process station A 110A. The gas control method and system can be similarly applied to process station B 110B. Suitable gas mixtures can be supplied to process station B 110B by gas supply device 104, and the gas mixtures can be the same as or different from the gas mixtures supplied to process station A 110A. Process station B 110B can include load port B 108B.

Measuring device 112 can measure CD of structures on the substrates. Measuring device 112 can be an optical metrology device, an optical inspection device, a profilometer, an SEM, a TEM, or other suitable measuring tools. In some embodiments, the CD measurement can be in-situ or substantially real-time. Measuring device 112 can include a loading port to receive and return the substrates. One or more sites can be measured across each substrate by measuring device 112. Multiple measurement sites can provide CD uniformity information across each substrate. The CD data must be within a predetermined range according to a specific device requirement or technology requirement. Measuring device 112 can be a stand-alone device. Measuring device 112 can transmit the CD data to computing device 102 by wired and/or wireless means.

Additional devices can be included in gas control system 100 and can be omitted for simplicity. These additional devices are within the spirit and the scope of this disclosure. Moreover, not all devices may be required to perform the disclosure provided herein.

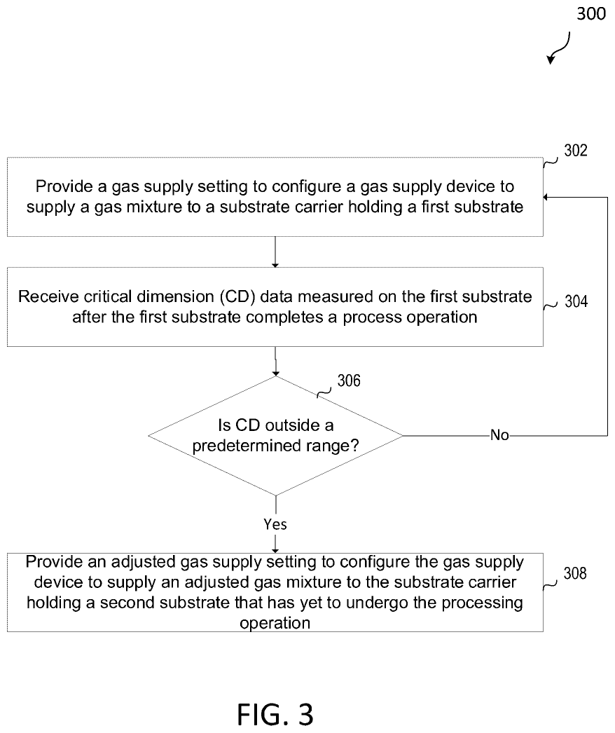

According to some embodiments, FIG. 3 is a flow diagram describing a method 300 for controlling gas supplies. FIGS. 4A-9C illustrate various applications of gas control method 300, in accordance with some embodiments. For ease of description, method 300 will be described generally first. In each application, the operations illustrated in FIG. 3 will be referred to and method 300 will be described specifically for each application. Additional operations can be performed between the various operations of method 300 and can be omitted for simplicity. These additional operations are within the spirit and the scope of this disclosure. Moreover, not all operations may be required to perform the disclosure provided herein. Additionally, some of the operations can be performed simultaneously or in a different order than the ones shown in FIG. 3. Method 300 can be performed by gas control system 100.

Referring to FIG. 3, in operation 302, a gas supply setting can be provided to configure a gas supply device to supply a gas mixture to a substrate carrier holding a first substrate. For example, the gas supply setting can be provided by computing device 102 of FIG. 1. In some embodiments, the gas supply setting can be provided by gas supply control 204 of FIG. 2. The gas mixture can be supplied by gas supply device 104 to substrate carrier 106 of FIG. 1. The gas supply setting can include types of one or more gases, amount of each of the one or more gases, flow rate of each of the one or more gases, supply duration of each of the one or more gases, and ratios of the one or more gases. The gas supply setting and the gas mixture can depend on the various applications, such as the various applications illustrated in FIGS. 4A-9C.

Referring to FIG. 3, in operation 304, after the first substrate completes a process operation, CD data can be measured on the first substrate. For example, the process operation can be performed on process station A 110A or process station B 110B. The CD data can be measured by measuring device 112. The CD data can be received by computing device 102 and the CD data can be analyzed by computing device 102. The CD data can include optical metrology data, optical inspection data, profilometer data, SEM data, or TEM data. The CD data can depend on the various applications, such as the various applications illustrated in FIGS. 4A-9C.

Referring to FIG. 3, in operation 306, a determination can be made whether the CD data is outside a predetermined range. For example, the determination whether the CD data is outside the predetermined range can be made by computing device 102. If the CD data is within the predetermined range, the same gas supply setting and gas mixture can be supplied to substrate carrier 106. In other words, operation 302 can be performed. In response to the CD data being outside the predetermined range, computing device 102 or gas supply control 204 can adjust the gas supply setting based on the CD data and method 300 can continue to operation 308. The predetermined range can depend on the various applications, such as the various applications illustrated in FIGS. 4A-9C.

Referring to FIG. 3, in operation 308, an adjusted gas supply setting can be provided to configure the gas supply device to supply an adjusted gas mixture to the substrate carrier holding a second substrate that has yet to undergo the process operation. For example, the adjusted gas supply setting can be provided by computing device 102 or gas supply control 204. The adjusted gas mixture can be supplied by gas supply device 104 to substrate carrier 106. The process operation can be performed on process station A 110A or process station B 110B. Based on the CD data, computing device 102 or gas supply control 204 can adjust the types of the one or more gases, the amount of each of the one or more gases, the flow rate of each of the one or more gases, the supply duration of each of the one or more gases, and the ratios of the one or more gases. The adjusted gas supply setting and the adjusted gas mixture can depend on the various applications, such as the various applications illustrated in FIGS. 4A-9C. The adjusted gas supply setting can assist the second substrate in achieving CD data within the predetermined range. If the CD data measured on the second substrate remains outside the predetermined range, further adjustments can be made to the gas supply settings. Because the CD data can be monitored and fed into the gas supply settings constantly or periodically, gas supplies to substrate carrier 106 can be controlled to yield CD data within the predetermined range. Gas control method 300 and the gas control system 100 can improve yield and quality.

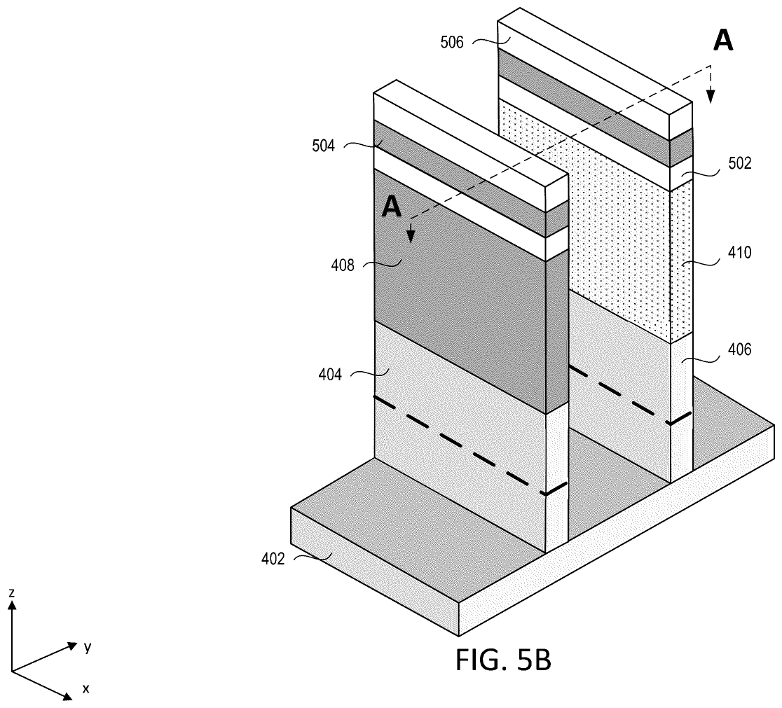

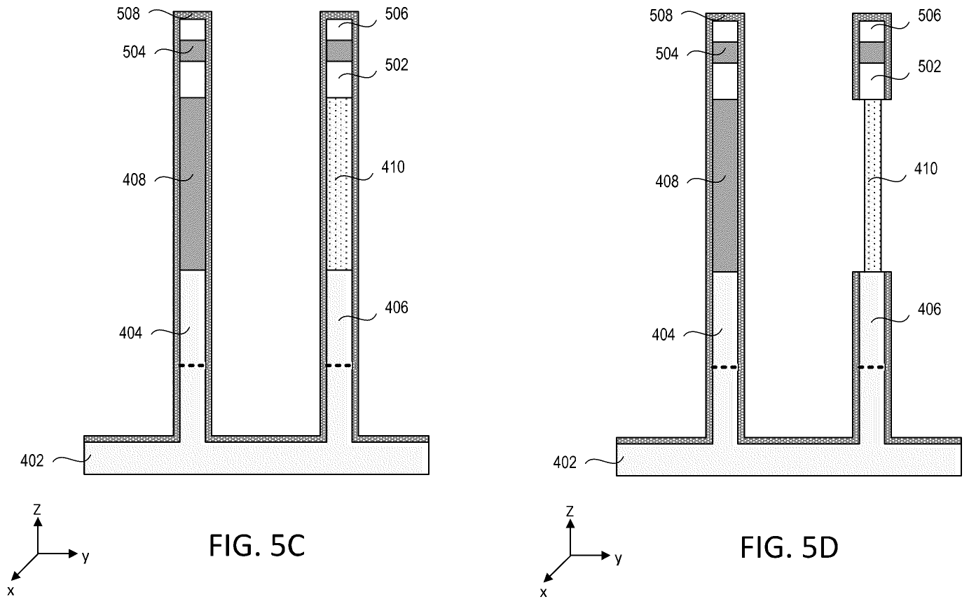

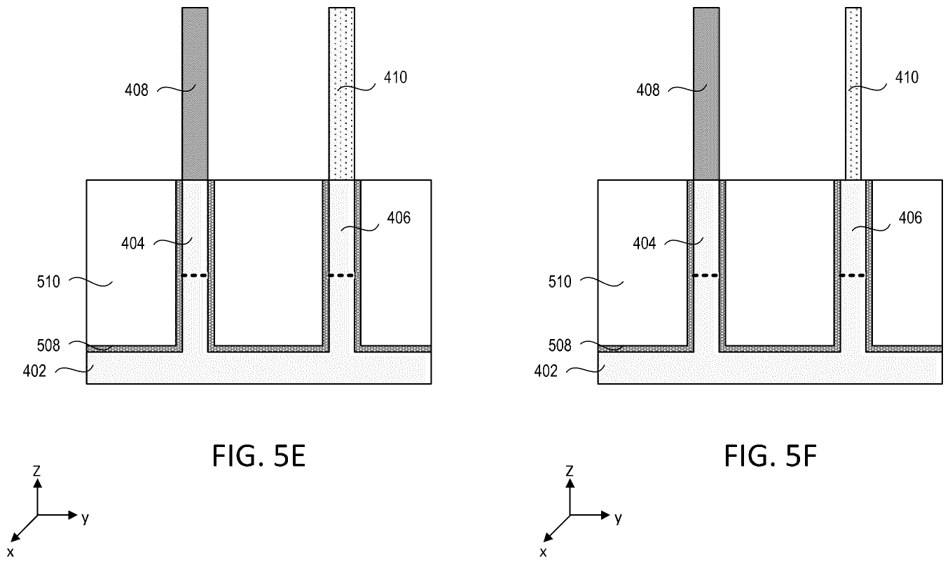

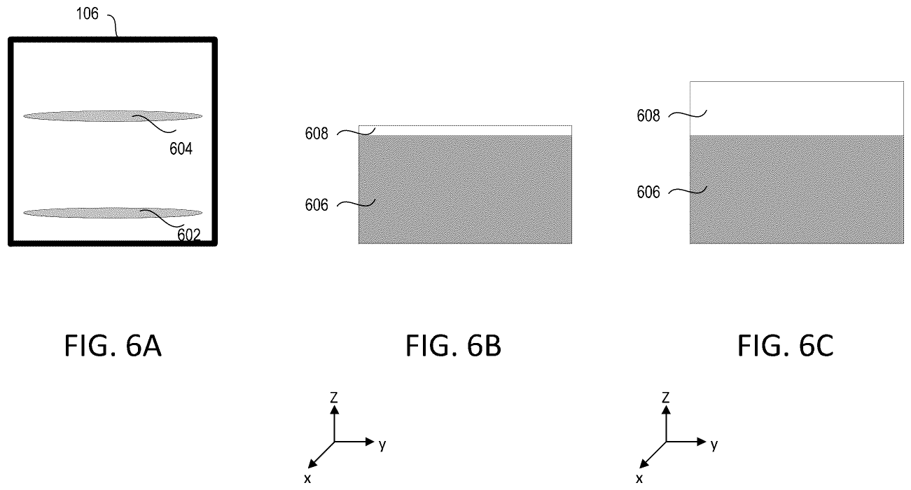

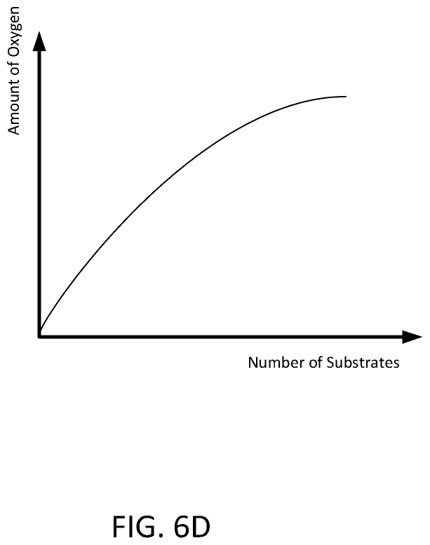

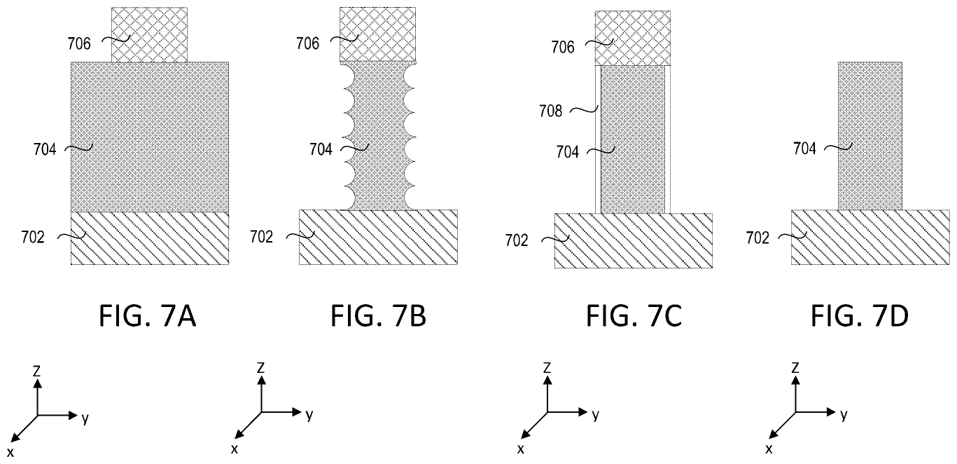

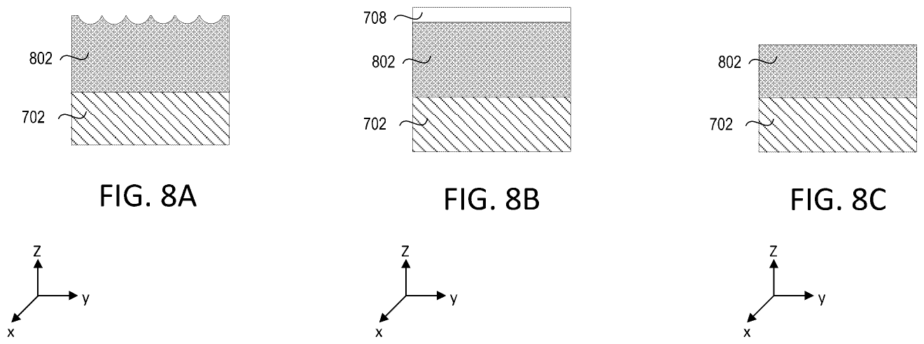

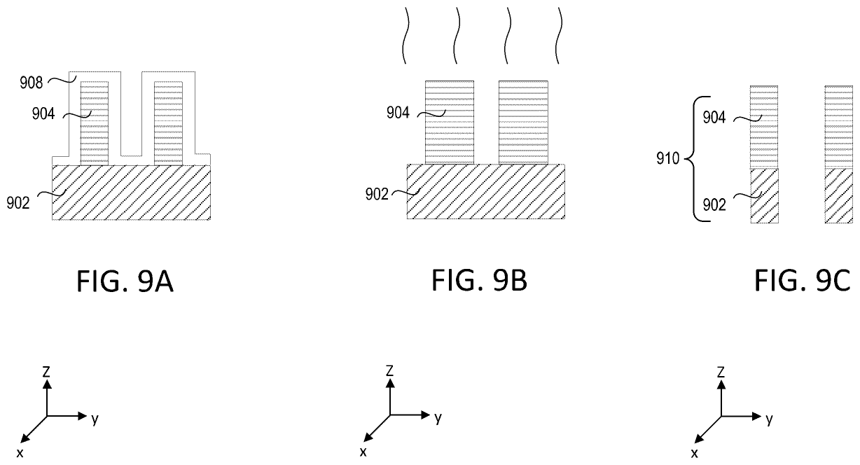

FIGS. 4A-9C illustrate various applications of gas control method 300, in accordance with some embodiments. FIGS. 4A and 4B illustrate an application where RH is controlled to reduce contamination. FIGS. 5A-5F illustrate an application where an inert gas is controlled to reduce oxidation loss. FIGS. 6A-6D illustrate an application where O₂ level is controlled to achieve a desired oxide layer thickness. FIGS. 7A-8C illustrate two applications where O₂ level is controlled to improve surface roughness. FIGS. 9A-9C illustrate an application where O₂ level is controlled to simplify CD trimming. The operations illustrated in FIG. 3 will be referred to and method 300 will be described specifically for each application. The discussion of elements in FIGS. 4A-6C and 7A-9C with the same annotations applies to each other, unless mentioned otherwise.

FIGS. 4A and 4B illustrate an application where RH is controlled to reduce contamination. Referring to FIGS. 4A and 4B, element 402 can be a substrate, such as Si. Element 404 can be a fin structure, such as Si, doped with p-type dopants, such as boron (B), indium (In), aluminum (Al), and gallium (Ga). Element 406 can be a fin structure, such as Si, doped with n-type dopants, such as phosphorous (P) and arsenic (As). Element 408 can be a fin structure, such as Si and SiGe. Element 410 can be a fin structure, such as Si and SiGe. Referring to FIG. 4A, element 412 can be etching byproducts, such as silicon fluoride (SiFₓ) and silicon chloride (SiClₓ). Etching byproducts 412 can be generated during etching processes using etchants containing Cl or F. Element 414 can be H₂O vapor. H₂O vapor 414 can exist in the fab air. H₂O vapor 414 can react with etching byproducts 412 to generate silicon oxide (SiOₓ), which can be solid contaminants on the surfaces of substrate 402, fin structure 404, and fin structure 406. Referring to FIG. 4B, contaminants 416 can adhere to the top surface of substrate 402, and the sidewalls of fin structures 404, 406, 408, and 410. Contaminants can cause low yield of devices. Therefore, RH is controlled to reduce contamination.

In applying method 300 to the scenario illustrated by FIGS. 4A and 4B, in operation 302, XCDA can be supplied by gas supply device 104 to substrate carrier 106 of FIG. 1 holding a first substrate. The XCDA can reduce RH in substrate carrier 106, thus reducing available H₂O vapor 414 to react with etching byproducts 412 of FIG. 4. Contaminants 416 can be reduced. In operation 304, the first substrate can be optically inspected by measuring device 112. A substrate map showing a percentage of areas with contaminants 416 compared with an entire area of the first substrate can be obtained. In operation 306, computing device 102 of FIG. 1 can determine if the percentage is above a threshold value. In response to the percentage being above the threshold value, in operation 308, computing device 102 can increase a flow rate setting of the XCDA. Gas supply device 104 can be configured to supply the XCDA with the higher flow rate to substrate carrier 106 holding a second substrate such that more H₂O vapor 414 can be removed from substrate carrier 106. Therefore, a percentage of areas with contaminants 416 compared with an entire area of the second substrate can be reduced. If the percentage remains above the threshold value, computing device 102 can make additional adjustments to the XCDA supply setting. The percentage monitoring and feedback can be performed constantly or periodically so that the XCDA supply to substrate carrier 106 can be controlled to yield percentage data below the predetermined threshold. In some embodiments, the RH can be controlled to be below about 30%. Gas control method 300 and gas control system 100 can improve yield and quality in the application where RH is controlled to reduce contamination. The structures illustrated by FIGS. 4A and 4B are not intended to be limiting. Gas control method 300 can be used to control contamination on any structures that have undergone an etching process using etchants containing Cl or F.

FIGS. 5A-5F illustrate an application where an inert gas is controlled to reduce oxidation loss. Referring to FIGS. 5A and 5B, element 502 can be a capping layer, such as crystalline Si. Element 504 can be a patterned layer, such as SiOₓ. Element 506 can be another patterned layer, such as silicon nitride (Si₃N₄). FIGS. 5C-5F are cross-sectional views of fin structures of FIG. 5B along line A-A. Element 508 can be a liner layer, such as SiOₓ. Element 510 can be a shallow trench isolation (STI) layer, such as SiOₓ. Referring to FIG. 5B, after fin structures 408 and 410 are patterned and before liner layer 508 is deposited, fin structures 408 and 410 can be susceptible to oxidation if they are exposed to the fab air or the XCDA. Referring to FIG. 5C, if fin structures 408 and 410 are protected from oxidation, there are no losses of fin structures 408 and 410 and liner layer 508 can be deposited on fin structures 408 and 410. Referring to FIG. 5D, if fin structures 408 and 410 are not protected from oxidation, there are losses of fin structure 410 and liner layer 508 cannot be deposited on fin structure 410, which will cause further fin structure oxidation and losses. Referring to FIG. 5E, if fin structures 408 and 410 are protected from oxidation, after capping layer 502, patterned layers 504 and 506, and portions of liner layer 508 are removed, protected fin structures 408 and 410 can have widths within a predetermined range. Referring to FIG. 5F, if fin structures 408 and 410 are not protected from oxidation, after capping layer 502, patterned layers 504 and 506, and portions of liner layer 508 are removed, unprotected fin structure 410 can have a width outside the predetermined range. For example, the width of fin structure 410 can be smaller than a lower threshold of the predetermined range. Thin fin structures can cause defects and low yield of devices. Therefore, an inert gas, such as N₂ and Ar, is controlled to reduce oxidation loss.

In applying method 300 to the scenario illustrated by FIGS. 5A-5F, in operation 302, an inert gas can be supplied by gas supply device 104 to substrate carrier 106 of FIG. 1 holding a first substrate. The inert gas can be supplied, for example, for about 30 s, during loading of the first substrate onto process station A 110A of FIG. 1. The inert gas can be supplied, for example, continuously, during the time the first substrate is processed on process station A 110A. The inert gas can be supplied, for example, between about 80 s and about 600 s, during unloading of the first substrate from process station A 110A. The inert gas can prevent fin structures 408 and 410 of FIGS. 5A-5F from being in contact with O₂ in the fab air or the XCDA. Oxidation loss can be reduced. In operation 304, CD data of fin structures 408 and 410 on the first substrate can be measured by measuring device 112 of FIG. 1, such as an SEM and a TEM. In operation 306, computing device 102 of FIG. 1 can determine if the CD data is outside a predetermined range. For example, computing device 102 can determine if the CD data is below a lower threshold of the predetermined range. In response to the CD data being below the lower threshold, in operation 308, computing device 102 can increase a flow rate setting or duration setting of the inert gas. Gas supply device 104 can be configured to supply the inert gas with the higher flow rate or the longer duration to substrate carrier 106 holding a second substrate such that more inert gas can be pumped into substrate carrier 106 to reduce O₂ present in substrate carrier 106. Therefore, oxidation loss can be reduced and CD data of fin structures 408 and 410 on the second substrate can be increased.

If the CD data remains below the lower threshold, computing device 102 can make additional adjustments to the inert gas supply setting. The CD data monitoring and feedback can be performed constantly or periodically so that the inert gas supply to substrate carrier 106 can be controlled to yield CD data within the predetermined range. Gas control method 300 and gas control system 100 can reduce fin structure defects and improve yield and quality in the application where an inert gas, such as N₂ and Ar, is controlled to reduce oxidation loss. The structures illustrated by FIGS. 5A-5F are not intended to be limiting. Gas control method 300 can be used to prevent oxidation on any structures that require protection, such as polysilicon, metal contacts, metal interconnects, and metal vias.

FIGS. 6A-6D illustrate an application where O₂ level is controlled to achieve a desired oxide layer thickness. Referring to FIG. 6A, elements 602 and 604 can be substrates, such as wafers. Substrates 602 and 604 can be located in different slots of substrate carrier 106 of FIG. 1. Therefore, during a process operation, substrates 602 and 604 can have different wait times in substrate carrier 106. For example, after substrate 602 completes the process operation, a wait time starts for substrate 602. Substrate 602 waits until all substrates, including substrate 604, complete the process operation. In comparison, if substrate 604 is in the last slot, there is no wait time for substrate 604 after substrate 604 completes the process operation. If substrate 604 is not in the last slot, substrate 604 waits until all wafers above substrate 604 complete the process operation. Therefore, the difference in wait time between substrates 602 and 604 can be the processing time for all the substrates in the slots between substrates 602 and 604 to complete the process operation plus loading and unloading time. Referring to FIGS. 6B and 6C, element 606 can be a layer that can be oxidized. For example, layer 606 can be copper (Cu), cobalt (Co), transition metal, Al, Si, and SiGe. Element 608 can be an oxide layer. For example, oxide layer 608 can be silicon germanium oxide (SiGeOₓ), SiOₓ, and metal oxide (MOₓ). In some embodiments, oxide layer 608 can function as a protective layer, adhesion layer, and/or a liner layer, and a separate process operation can be included to form oxide layer 608. In some embodiments, oxide layer 608 can be a natural oxide layer formed in the fab air or the XCDA. However, when substrates 602 and 604 are exposed to the fab air or the XCDA and due to the different wait times for substrates 602 and 604, different thicknesses of oxide layer 608 can be formed. For example, because substrate 602 has a longer wait time, oxide layer 608 on substrate 602 can be thicker, as shown in FIG. 6C. Because substrate 604 has a shorter wait time, oxide layer 608 on substrate 604 can be thinner, as shown in FIG. 6B. Non-uniformity of thicknesses of oxide layer 608 can cause process variations in a next process operation, which requires a more complicated process control. Therefore, O₂ level is controlled to achieve a desired oxide layer thickness.

In applying method 300 to the scenario illustrated by FIGS. 6A-6C, in operation 302, a sequence of first inert gas/second inert gas/O₂/third inert gas can be supplied by gas supply device 104 to substrate carrier 106 of FIG. 1 holding a first batch of substrates. The first inert gas can be supplied, for example, between about 10 s and about 30 s, during loading of each of the first batch of substrates onto process station A 110A. The second inert gas can be supplied, for example, continuously, during the time each of the first batch of substrates is processed on process station A 110A. The O₂ can be supplied, for example, between about 10 s and about 600 s, during unloading of each of the first batch of substrates from process station A 110A. The third inert gas can be supplied, for example, for about 80 s, following the O₂ during unloading of each of the first batch of substrates from process station A 110A. The amount, ratio, and flow rate of the O₂ can determine the degree of oxidation of layer 606 of FIG. 6. For example, for full or complete oxidation, pure O₂ can be used and the duration can be longer. For partial oxidation, O₂ mixed with an inert gas can be used and the duration can be shorter. In some embodiments, the percentage of O₂ in the gas mixture can be between about 0.5% and about 20%. Because the amount of the O₂ is controlled, each of the first batch of substrates is exposed to the same amount of the O₂. The substrates are also protected by the inert gas from the fab air or the XCDA during other times. Therefore, a uniform thickness of oxide layer 608 can be formed on each of the first batch of substrates.

In operation 304, thicknesses of oxide layer 608 on each of the first batch of substrates can be measured by measuring device 112 of FIG. 1, such as an optical metrology device like a spectrometer. In operation 306, computing device 102 of FIG. 1 can determine if the thicknesses are outside a predetermined range and if the uniformity of the thicknesses is outside a predetermined range. For example, computing device 102 can determine if the thicknesses are outside the predetermined range and if the uniformity is below a threshold value. In response to the thicknesses being outside the predetermined range or the uniformity being below the threshold value, in operation 308, computing device 102 can adjust a flow rate setting, an amount setting, a ratio setting, and/or a duration setting of the O₂. Gas supply device 104 can be configured to supply the O₂ with the adjusted flow rate, amount, ratio, and/or duration to substrate carrier 106 of FIG. 1 holding a second batch of substrates. Therefore, thicknesses of oxide layer 608 on each of the second batch of substrates can be adjusted and uniformity of the thicknesses on the second batch of substrates can be improved.

If the thicknesses are still outside the predetermined range or if the uniformity remains below the threshold value, computing device 102 can make additional adjustments to the O₂ supply setting. The thickness and uniformity monitoring and feedback can be performed constantly or periodically so that the O₂ supply to substrate carrier 106 can be controlled to yield thicknesses and uniformity data within the predetermined ranges. Gas control method 300 and gas control system 100 can improve the uniformity and improve yield and quality in the application where O₂ level is controlled to achieve a desired oxide layer thickness. The structures illustrated by FIGS. 6A-6C are not intended to be limiting. Gas control method 300 can be used to form a uniform oxide layer on any structures that desire such oxidation.

In some embodiments, natural oxidation can take place when substrate carrier 106 is being transferred from process station A 110A to process station B 110B of FIG. 1 or on stand-by. Having the natural oxidation take place on stand-by can eliminate a separate oxidation process operation, save cycle time, and reduce process complexity. In applying method 300 to the stand-by oxidation scenario, in operation 302, before substrate carrier 106 is disconnected from process station A 110A, a controlled amount of O₂ can be injected by gas supply device 104 into substrate carrier 106 holding a first batch of substrates. For example, O₂ mixed with an inert gas can be injected into substrate carrier 106. In some embodiments, the percentage of the O₂ in the gas mixture can be between about 0.5% and about 5%. Once the amount of the O₂ is exhausted, the thicknesses of oxide layer 608 can be maintained, no matter how much longer substrates 602 and 604 stay in substrate carrier 106. As illustrated in FIG. 6D, the amount of the O₂ can be correlated to the number of substrates. The correlation can be linear, hyperbolic, or based on any other function.

Referring to FIG. 3, in operation 304, after the stand-by oxidation is complete and the thickness of oxide layer 608 of FIG. 6 on each of the first batch of substrates is stabilized (e.g., after O₂ is exhausted in substrate carrier 106 and oxide thickness on each of the first batch of substrates stops changing), thicknesses can be measured by measuring device 112 of FIG. 1, such as a spectrometer. Referring to FIG. 3, in operation 306, computing device 102 of FIG. 1 can determine if the thicknesses are outside a predetermined range and if the uniformity of the thicknesses is outside a predetermined range. For example, computing device 102 can determine if the thicknesses are outside the predetermined range and if the uniformity is below a threshold value. In response to the thicknesses being outside the predetermined range or the uniformity being below the threshold value, in operation 308, computing device 102 can adjust an amount setting or a ratio setting. Gas supply device 104 can be configured to supply the O₂ with the adjusted amount or ratio to substrate carrier 106 holding a second batch of substrates. Therefore, thicknesses of oxide layer 608 on each of the second batch of substrates can be adjusted and uniformity of the thicknesses on the second batch of substrates can be improved. If the thicknesses remain outside the predetermined range or if the uniformity remains below the threshold value, computing device 102 can make additional adjustments to the O₂ supply setting. The thicknesses and uniformity monitoring and feedback can be performed constantly or periodically so that the O₂ supply to substrate carrier 106 can be controlled to yield thickness and uniformity data within the predetermined range.

FIGS. 7A-8C illustrate two applications where O₂ level is controlled to improve surface roughness. FIGS. 7A-7D illustrate an etching process. FIGS. 8A-8C illustrate a deposition process. Referring to FIGS. 7A-7D, element 702 can be a substrate structure. Element 704 can be a layer to be etched. Element 706 can be a photoresist pattern. Element 708 can be an oxide layer. After layer 704 is etched based on photoresist pattern 706, sidewalls of layer 704 can have areas with different dangling bonds. Areas with less dangling bonds can react with O₂ more slowly, and there can be less oxidation loss. Areas with more dangling bonds can react with O₂ faster, and there can be more oxidation loss. As shown in FIG. 7B, if the sidewalls of layer 704 are exposed to the fab air or the XCDA, surface roughness can be high due to the different oxidation loss on the sidewalls.

Referring to FIGS. 8A-8C, element 802 can be a layer to be deposited. After layer 802 is deposited, a top surface of layer 802 can have areas with different dangling bonds. Areas with less dangling bonds can react with O₂ more slowly, and there can be less oxidation loss. Areas with more dangling bonds can react with O₂ faster, and there can be more oxidation loss. As shown in FIG. 8A, if the top surface of layer 802 is exposed to the fab air or the XCDA, surface roughness can be high due to the different oxidation loss on the top surface. High surface roughness can cause process variations in a next process operation, which requires a more complicated process control. As shown in FIGS. 7C and 8B, if a uniform oxide layer, such as oxide layer 708, is formed on the sidewalls of layer 704 and the top surface of layer 802, there may not be different oxidation loss in areas with different dangling bonds. After oxide layer 708 is removed, layer 704 and layer 802 can have the sidewalls and the top surface with low surface roughness, as shown in FIGS. 7D and 8C. Therefore, O₂ level is controlled to improve surface roughness.

In applying method 300 to the scenarios illustrated by FIGS. 7A-8C, in operation 302, a sequence of first inert gas/second inert gas/O₂/third inert gas can be supplied by gas supply device 104 to substrate carrier 106 of FIG. 1 holding a first substrate. The first inert gas can be supplied, for example, between about 10 s and about 30 s, during loading of the first substrate onto process station A 110A. The second inert gas can be supplied, for example, continuously, during the time the first substrate is processed on process station A 110A. The O₂ can be supplied, for example, between about 10 s and about 600 s, during unloading of the first substrate from process station A 110A. The third inert gas can be supplied, for example, for about 80 s, following the O₂ during unloading of the first substrate from process station A 110A. In some embodiments, pure O₂ can be used. In some embodiments, O₂ mixed with an inert gas can be used, and the percentage of O₂ in the gas mixture can be between about 0.5% and about 20%. Because the amount of the O₂ is controlled and the first substrate is protected by the inert gas from the fab air or the XCDA during other times, a uniform thickness of oxide layer 708 can be formed on the sidewalls of layer 704 and the top surface of layer 802.

In operation 304, after oxide layer 708 is removed, surface roughness of the sidewalls of layer 704 and the top surface of layer 802 on the first substrate can be measured by measuring device 112 of FIG. 1, such as a metrology device like a profilometer, SEM, and TEM. In operation 306, computing device 102 of FIG. 1 can determine if the surface roughness is outside a predetermined range. For example, computing device 102 can determine if the surface roughness is above a threshold value. In response to the surface roughness being above the threshold value, in operation 308, computing device 102 can adjust a flow rate setting, an amount setting, a ratio setting, and/or a duration setting of the O₂. Gas supply device 104 of FIG. 1 can be configured to supply the O₂ with the adjusted flow rate, amount, ratio, and/or duration to substrate carrier 106 holding a second substrate. Therefore, surface roughness of the sidewalls of layer 704 and the top surface of layer 802 on the second substrate can be reduced. If the surface roughness remains above the threshold value, computing device 102 can make additional adjustments to the O₂ supply setting. The surface roughness monitoring and feedback can be performed constantly or periodically so that the O₂ supply to substrate carrier 106 can be controlled to yield surface roughness data below the threshold value. Gas control method 300 and gas control system 100 can improve yield and quality in the application where O₂ level is controlled to improve surface roughness. The structures illustrated by FIGS. 7A-8C are not intended to be limiting. Gas control method 300 can be used to any structures that desire a controlled surface roughness.

FIGS. 9A-9C illustrate an application where O₂ level is controlled to simplify CD trimming. Referring to FIGS. 9A-9C, element 902 can be a substrate structure. Element 904 can be a patterned layer. FIG. 9C shows structure 910 with a desired CD. A method of forming structure 910 is shown in FIG. 9B. Patterned layer 904 can be formed with a size larger than the desired CD. CD trimming, such as dry etching, can be used to trim patterned layer 904 and substrate structure 902 to form structure 910 with the desired CD. However, CD trimming conditions can be difficult to control and variations in the final CD can be significant. Another method of forming structure 910 is shown in FIG. 9A. Patterned layer 904 can be formed with the same size as the desired CD. A uniform oxide layer, such as oxide layer 908, can be formed on patterned layer 904. Oxide layer 908 and portions of substrate structure 902 can be removed to form structure 910 with the desired CD. Because oxide layer 908 can be formed in a controlled manner, CD trimming is not needed and operations to form structure 910 with the desired CD can be simplified. Therefore, O₂ level is controlled to simplify CD trimming.

In applying method 300 to the scenario illustrated by FIGS. 9A-9C, in operation 302, a sequence of first inert gas/second inert gas/O₂/third inert gas can be supplied by gas supply device 104 to substrate carrier 106 of FIG. 1 holding a first substrate. The first inert gas can be supplied, for example, between about 10 s and about 30 s, during loading of the first substrate onto process station A 110A of FIG. 1. The second inert gas can be supplied, for example, continuously, during the time the first substrate is processed on process station A 110A. The O₂ can be supplied, for example, between about 10 s and about 600 s, during unloading of the first substrate from process station A 110A. The third inert gas can be supplied, for example, for about 80 s, following the O₂ during unloading of the first substrate from process station A 110A. In some embodiments, pure O₂ can be used. In some embodiments, O₂ mixed with an inert gas can be used and the percentage of O₂ in the gas mixture can be between about 0.5% and about 20%. Because the amount of the O₂ is controlled and the first substrate is protected by the inert gas from the fab air or the XCDA during other times, a uniform thickness of oxide layer 908 can be formed on patterned layer 904.

Referring to FIG. 3, in operation 304, after oxide layer 908 is removed, CD data of structure 910 on the first substrate can be measured by measuring device 112 of FIG. 1, such as an SEM and a TEM. In operation 306, computing device 102 of FIG. 1 can determine if the CD data is outside a predetermined range. In response to the CD data being outside the predetermined range, in operation 308, computing device 102 can adjust a flow rate setting, an amount setting, a ratio setting, and/or a duration setting of the O₂. Gas supply device 104 of FIG. 1 can be configured to supply the O₂ with the adjusted flow rate, amount, ratio, and/or duration to substrate carrier 106 holding a second substrate. Therefore, CD data of structure 910 on the second substrate can be adjusted. If the CD data remains outside the predetermined range, computing device 102 can make additional adjustments to the O₂ supply setting. The CD data monitoring and feedback can be performed constantly or periodically so that the O₂ supply to substrate carrier 106 can be controlled to yield CD data within the predetermined range. Gas control method 300 and gas control system 100 can control CD data and improve yield and quality in the application where O₂ level is controlled to simplify CD trimming. The structures illustrated by FIGS. 9A-9C are not intended to be limiting. Gas control method 300 can be used to form any structures that desire a controlled CD without complicated CD trimming.

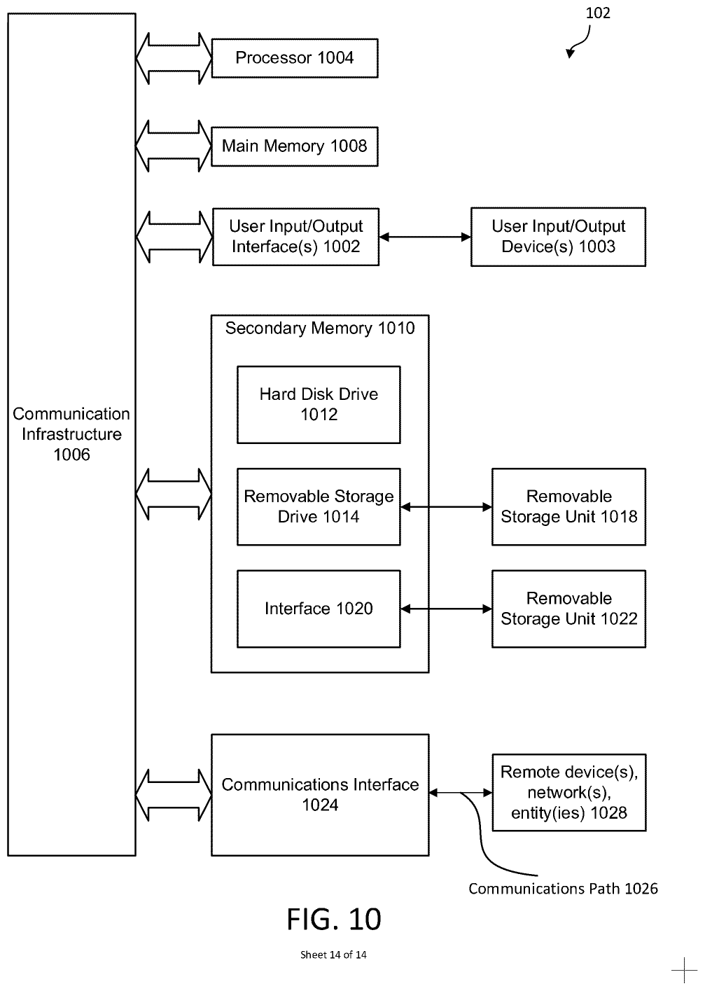

FIG. 10 is an illustration of an example computing device 102 of FIG. 1 in which various embodiments of the present disclosure can be implemented, according to some embodiments. Computing device 102 can be a computer capable of performing the functions and operations described herein. For example, and without limitation, computing device 102 can be capable of receiving, processing, and transmitting signals and commands. Computing device 102 can be used, for example, to receive CD data, analyze the CD data, and adjust gas supply settings based on the CD data. Computing device 102 can be used, for example, to send gas supply settings to gas supply device 104 and configure gas supply device 104 of FIG. 1 based on the gas supply settings.

Computing device 102 includes one or more processors (also called central processing units, or CPUs), such as a processor 1004. Processor 1004 is connected to a communication infrastructure or bus 1006. Computing device 102 also includes input/output device(s) 1003, such as touch screens, monitors, keyboards, pointing devices, etc., that communicate with communication infrastructure or bus 1006 through input/output interface(s) 1002. Computing device 102 can receive instructions to implement functions and operations described herein—e.g., receiving the CD data, analyzing the CD data, adjusting the gas supply settings, sending the gas supply setting, configuring gas supply device 104, and method 300—via input/output device(s) 1003. Computing device 102 can also include a main or primary memory 1008, such as random access memory (RAM). Main memory 1008 can include one or more levels of cache. Main memory 1008 has stored therein control logic (e.g., computer software) and/or data. In some embodiments, the control logic (e.g., computer software) and/or data can include one or more of the functions described above with respect to receiving the CD data, analyzing the CD data, adjusting the gas supply settings, sending the gas supply setting, configuring gas supply device 104, and method 300.

Computing device 102 can also include one or more secondary storage devices or secondary memory 1010. Secondary memory 1010 can include, but is not limited to, a hard disk drive 1012 and/or a removable storage device or drive 1014. Removable storage drive 1014 can be a floppy disk drive, a magnetic tape drive, a compact disk drive, an optical storage device, tape backup device, and/or any other storage device/drive.

Removable storage drive 1014 can interact with a removable storage unit 1018. Removable storage unit 1018 includes a computer usable or readable storage device having stored thereon computer software (control logic) and/or data. Removable storage unit 1018 can be a floppy disk, magnetic tape, compact disk, DVD, optical storage disk, and/or any other computer data storage device. Removable storage drive 1014 reads from and/or writes to removable storage unit 1018 in a well-known manner.

According to some embodiments, secondary memory 1010 can include other means, instrumentalities or other approaches for allowing computer programs and/or other instructions and/or data to be accessed by computing device 102. Such means, instrumentalities or other approaches can include, but is not limited, a removable storage unit 1022 and an interface 1020. Examples of the removable storage unit 1022 and the interface 1020 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. In some embodiments, secondary memory 1010, removable storage unit 1018, and/or removable storage unit 1022 can include one or more of the functions described above with respect to the holder.

Computing device 102 can further include a communication or network interface 1024. Communication interface 1024 enables computing device 102 to communicate and interact with any combination of remote devices, remote networks, remote entities, etc. (individually and collectively referenced by reference number 1028). For example, communication interface 1024 can allow computing device 102 to communicate with element 1028 (e.g., remote devices) over communications path 1026, which can be wired and/or wireless, and which can include any combination of LANs, WANs, the Internet, etc. Control logic and/or data can be transmitted to and from computing device 102 via communication path 1026.

The functions/operations in the preceding embodiments can be implemented in a wide variety of configurations and architectures. Therefore, some or all of the operations in the preceding embodiments—e.g., receiving the CD data, analyzing the CD data, adjusting the gas supply settings, sending the gas supply setting, configuring gas supply device 104, and method 300—can be performed in hardware, in software or both. In some embodiments, a tangible system or article of manufacture including a tangible computer useable or readable medium having control logic (software) stored thereon is also referred to herein as a computer program product or program storage device. This includes, but is not limited to, computing device 102, main memory 1008, secondary memory 1010 and removable storage units 1018 and 1022, as well as tangible articles of manufacture embodying any combination of the foregoing. Such control logic, when executed by one or more data processing devices (such as computing device 102), causes such data processing devices to operate as described herein. In some embodiments, computing device 102 includes hardware/equipment for the manufacturing of photomasks and circuit fabrication. For example, the hardware/equipment can be connected to or be part of element 1028 (remote device(s), network(s), entity(ies) 1028) of computing device 102.

The present disclosure is directed to a method (e.g., method 300) for providing gas control to substrate carriers (e.g., substrate carrier 106) based on critical dimension (CD) data feedback and an example system (e.g., system 100) for performing the method. In some embodiments, a computing device (e.g., computing device 102) can provide a gas supply setting to configure a gas supply device (e.g., gas supply device 104) to supply a gas mixture to a substrate carrier holding a first substrate. After the first substrate completes a process operation, CD data can be measured on the first substrate. The computing device can receive and analyze the CD data measured on the first substrate. The CD data can depend on the different process operations and can include optical metrology data, optical inspection data, profilometer data, scanning electron microscopy (SEM) data, transmission electron microscopy (TEM) data, or a combination thereof. In response to the CD data being outside a predetermined range, the computing device can provide an adjusted gas supply setting to configure the gas supply device to supply an adjusted gas mixture to the substrate carrier holding a second substrate that has yet to undergo the process operation. Based on the CD data, the computing device can adjust the types of the one or more gases, the amount of each of the one or more gases, the flow rate of each of the one or more gases, the supply duration of each of the one or more gases, and the ratios of the one or more gases. The adjusted gas supply setting can assist the second substrate in achieving CD data within the predetermined range.

If the CD data measured on the second substrate remains outside the predetermined range, further adjustments can be made to the gas supply settings. Because the CD data can be monitored and fed into the gas supply settings constantly or periodically, gas supplies to the substrate carriers can be controlled to yield the CD data within the predetermined range. The gas control method and system can improve yield and quality. For example, the gas control method and system can reduce surface contaminants and oxidation loss. In some embodiments, the gas control method and system can facilitate oxidation while the substrates wait in the substrate carriers. The gas control method and system can also reduce oxidation time for the substrates during an oxidation process operation and can therefore reduce process cycle time and improve production efficiency. Because the gases in the substrate carriers can be controlled, and the substrate carriers can be airtight, the substrate carriers can function as environmentally-controlled waiting stations. A number of gas-filled waiting stations can be reduced, which can save cleanroom floor space and reduce the operation costs.

In some embodiments, a method includes providing a first setting to configure a gas supply device to supply a first gas mixture to a substrate carrier holding a first substrate. The method further includes receiving critical dimension (CD) data measured on the first substrate after the first substrate completes a process operation. The method further includes, in response to the CD data being outside a predetermined range, providing a second setting to configure the gas supply device to supply a second gas mixture to the substrate carrier holding a second substrate that has yet to undergo the process operation.

In some embodiments, the method includes receiving a gas supply setting and supplying, to a substrate carrier holding a first substrate, a gas mixture based on the gas supply setting. The method further includes receiving an adjustment in the gas supply setting based on critical dimension (CD) data measured on the first substrate after the first substrate completes a process operation, where the adjusted gas supply setting is in response to the CD data being outside a predetermined range. The method further includes supplying, to the substrate carrier holding a second substrate that has yet to undergo the process operation, the gas mixture based on the adjusted gas supply setting.

In some embodiments, a system includes a computing device configured to generate first and second gas supply settings, a process station configured to perform a process operation, and a substrate carrier configured to hold first and second substrates. The system further includes a gas supply device configured to receive, from the computing device, the first gas supply setting and supply, to the substrate carrier holding the first substrate, a first gas mixture. The gas supply device is further configured to receive, from the computing device, the second gas supply setting in response to critical dimension (CD) data measured on the first substrate being outside a predetermined range, where the CD data is measured after the first substrate completes the process operation on the process station. The gas supply device is further configured to supply, to the substrate carrier holding the second substrate, a second gas mixture based on the second gas supply setting prior to the second substrate undergoing the process operation on the process station.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A system, comprising:
a computing device configured to generate first and second gas supply settings;
a process station configured to perform a process operation;
a substrate carrier configured to hold first and second substrates; and
a gas supply device configured to:
receive, from the computing device, the first gas supply setting;
supply, to the substrate carrier holding the first substrate, a first gas mixture;
receive, from the computing device, the second gas supply setting in response to critical dimension (CD) data measured on the first substrate being outside a predetermined range, wherein the CD data is measured after the first substrate completes the process operation on the process station; and
supply, to the substrate carrier holding the second substrate, a second gas mixture based on the second gas supply setting prior to the second substrate undergoing the process operation on the process station.

2. The system of claim 1, wherein the first and second gas mixtures comprise oxygen (O₂) to oxidize a structure on the first and second substrates.

3. The system of claim 1, wherein the computing device is further configured to generate a third gas supply setting, and wherein the gas supply device is further configured to:
receive the third gas supply setting; and
supply, to the substrate carrier, a third gas mixture based on the third gas supply setting, wherein the first gas mixture comprises an inert gas comprising nitrogen (N₂) or argon (Ar) to protect a structure on the first substrate from oxidation and the third gas mixture comprises O₂ to oxidize the structure.

4. The system of claim 1, wherein the computing device is further configured to generate a third gas supply setting and the gas supply device is further configured to:
receive the third gas supply setting; and
supply, to the substrate carrier, a third gas mixture based on the third gas supply setting, wherein the third gas mixture remains in the substrate carrier after the substrate carrier is disconnected from the process station.

5. The system of claim 1, wherein the first and second gas supply settings comprise types of one or more gases, an amount of each of the one or more gases, a flow rate of each of the one or more gases, a supply duration of each of the one or more gases, and ratios between the one or more gases.

6. The system of claim 1, wherein:
the gas supply device is further configured to supply a first gas mixture comprising O₂; and
the computing device is further configured to adjust the first gas supply setting based on a percentage of O₂ supplied to the substrate carrier correlated to a number of substrates in the substrate carrier.

7. The system of claim 1, wherein the computing device is further configured to calculate the second gas supply setting based on a multiple regression analysis model receiving the CD data.

8. The system of claim 1, further comprising a metrology system configured to measure the CD data.

9. The system of claim 8, wherein the metrology system comprises a spectrometer, a profilometer, a scanning electron microscope, a transmission electron microscope, or a combination thereof.

10. A system, comprising:
a substrate carrier, comprising:
a first substrate holder configured to hold a first substrate; and
a second substrate holder configured to hold a second substrate;
a computing device configured to communicate a gas supply setting; and
a gas supply device configured to:
receive a gas supply setting from the computing device;
supply a gas mixture to the substrate carrier based on the gas supply setting;
receive an adjustment in the gas supply setting based on critical dimension (CD) data measured on the first substrate after the first substrate completes a process operation, wherein the adjusted gas supply setting is calculated by the computing device in response to the CD data being outside a predetermined range; and
supply, to the second substrate holder, the gas mixture based on the adjusted gas supply setting.

11. The system of claim 10, wherein the gas supply device is further configured to:
receive an other gas supply setting; and
supply, to the substrate carrier, an other gas mixture based on the other gas supply setting, wherein the other gas mixture remains in the substrate carrier when the substrate carrier transfers the first and second substrates from a first process station to a second process station.

12. The system of claim 10, further comprising a metrology device configured to measure the CD data.

13. The system of claim 12, wherein the metrology device comprises a spectrometer, a profilometer, a scanning electron microscope, a transmission electron microscope, or a combination thereof.

14. The system of claim 10, wherein the adjusted gas supply setting comprises one or more of an adjusted duration and an adjusted flow rate of nitrogen (N₂) or oxygen (O₂) in the gas mixture.

15. The system of claim 10, wherein computing device is further configured to calculate the adjusted gas supply setting based on a multiple regression analysis model receiving the CD data.

16. A system, comprising:
a process station configured to perform a process operation;
a substrate carrier comprising a first substrate chuck and a second substrate chuck; and
a gas supply device configured to:
receive a first gas supply setting;
supply, to the first substrate chuck holding a first substrate, a first gas mixture;
receive a second gas supply setting in response to critical dimension (CD) data measured on the first substrate being outside a predetermined range, wherein the CD data is measured after the first substrate completes the process operation on the process station; and
supply, to the second substrate chuck holding a second substrate, a second gas mixture based on the second gas supply setting prior to the second substrate undergoing the process operation on the process station.

17. The system of claim 16, further comprising a computing device configured to generate and receive first and second gas supply settings.

18. The system of claim 17, wherein the computing device is further configured to generate a third gas supply setting, and wherein the gas supply device is further configured to:
receive the third gas supply setting; and
supply, to the substrate carrier, a third gas mixture based on the third gas supply setting, wherein the first gas mixture comprises an inert gas including nitrogen (N₂) or argon (Ar) to protect a structure on the first substrate from oxidation and the third gas mixture comprises oxygen (O₂) to oxidize the structure.

19. The system of claim 17, wherein the computing device is further configured to generate a third gas supply setting, and wherein the gas supply device is further configured to:
receive the third gas supply setting; and
supply, to the substrate carrier, a third gas mixture based on the third gas supply setting, wherein the third gas mixture remains in the substrate carrier after the substrate carrier is disconnected from the process station.

20. The system of claim 16, wherein the first and second gas mixtures comprise O₂ to oxidize a structure on the first and second substrates.
